(19) United States
(12) Patent Application Publication
(10) Pub. No.: US 2025/0356909 A1
(43) Pub. Date: Nov. 20, 2025

(54) SCALING BANDWIDTH ON HIGH BANDWIDTH MEMORY DEVICES AND ASSOCIATED SYSTEMS AND METHODS

(71) Applicant: Micron Technology, Inc., Boise, ID (US)

(72) Inventors: Sujeet Ayyapureddi, Boise, ID (US); Raghukiran Sreeramaneni, Frisco, TX (US)

(21) Appl. No.: 19/201,529

(22) Filed: May 7, 2025

Related U.S. Application Data
(60) Provisional application No. 63/647,437, filed on May 14, 2024.

(51) Int. Cl. G11C 11/4093; G11C 11/4076; G11C 11/4096

(52) U.S. Cl. CPC G11C 11/4093; G11C 11/4076; G11C 11/4096

(57) ABSTRACT

A system-in-package (SiP) device that includes a base substrate and a processing unit. The SiP also includes a high bandwidth memory (HBM) device that is electrically coupled to the processing unit. The HBM device includes an interface die, which has a bus switching circuit configured to select a through-silicon via (TSV) bus from a plurality of TSV buses, where each TSV bus has a set of TSVs. The bus switching circuit also communicatively couples a DQ bus having a set of DQ pins to the selected TSV bus. The HBM device also includes one or more stacks, with each stack having one or more dies. Each die includes a TSV bus select circuit that communicatively couples a bank group of the die to the TSV bus selected by the bus switching circuit of the interface die. The DQ bus can correspond to a pseudo-channel or channel of the HBM device.

### CROSS-REFERENCE TO RELATED APPLICATION(S)

The present application claims priority to U.S. Provisional Patent Application No. 63/647,437, filed May 14, 2024, the disclosure of which is incorporated herein by reference in its entirety.

### TECHNICAL FIELD

The present technology is generally related to vertically stacked semiconductor devices and more specifically to vertically stacked high bandwidth storage devices for semiconductor packages.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through substrate (silicon) vias (TSVs) between the dies and the support substrate.

### BRIEF DESCRIPTION OF THE DRAWINGS

FIG. 1 is a partially schematic cross-sectional diagram of a system-in-package device that is consistent with the present disclosure.

FIG. 2 is a simplified related art timing diagram for data flow through the TSVs.

FIG. 3 is a block diagram of an embodiment of a HBM device that is consistent with the present disclosure.

FIG. 4A is a schematic block diagram of a bus switching circuit that can be incorporated in the HBM device of FIG. 3.

FIG. 4B is an embodiment of a switch than be used in the bus switching circuit of FIG. 3.

FIG. 4C is a schematic block diagram of a TSV select circuit that can be incorporated in the HBM device of FIG. 3.

FIG. 5A is a simplified timing diagram for data flow through the TSVs during write operations that is consistent with the present disclosure.

FIG. 5B is a simplified timing diagram for data flow through the TSVs during read operations that is consistent with the present disclosure.

FIG. 6 is a flow chart that shows a method of communicatively coupling a DQ bus to a TSV bus that is consistent with the present disclosure.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, higher data bandwidth, lower power consumption, and reduced chip size are features that are demanded from semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D and 3D memory devices are formed by stacking memory dies vertically and interconnecting the dies using through-silicon (or through-substrate) vias (TSVs). The memory dies can be grouped in “stacks” with each stack, designated by a stack ID (“SID”), having one or more dies (e.g., 4 dies). Benefits of the 2.5D and 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5 and 3D memory devices contribute to higher memory access speed, lower power consumption, and chip size reduction. Example 2.5D and/or 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device). In the description below, the terms “stack” and “SID” are used interchangeably.

In a system-in-package (SiP) configuration, HBM devices may be integrated with a host device (e.g., a graphics processing unit (GPU), computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between GPU/CPU and the HBM device and/or provides mechanical support for the components of a SiP device) through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU/TCU, etc.) and HBM devices during operation. For example, the high bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system. It will be appreciated that such high bandwidth data transfer between the host device and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

Market demands on SiP devices and/or the HBM devices therein can present certain challenges, however. One such challenge is that demands on SiP devices (and the HBM devices therein) require the devices to continually increase bandwidth and corresponding DQ pin data rates. The increased data rates means that the data paths in the HBM device operate at tight timing margins. For example, the timing parameter t_{CCDR}, which corresponds to 2 CLK cycles, can degrade. In addition, higher bandwidths mean running the HBM device faster (e.g., a faster system clock frequency), which results in increased power consumption. Accordingly, it is desirable to increase the bandwidth on the HBM device while maintaining the same memory array timing, keeping t_{CCDR} CLK cycles at 2 CLK cycles, and keeping power consumption as low as possible.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although primarily discussed herein in the context of 2.5D HBM devices for SiP devices, one of skill in the art will understand that the scope of the present disclosure is not so limited. For example, various components of the SiP devices described herein can also be implemented in 3D HBM devices and various other stacked semiconductor devices to help with issues related to high data rates as discussed above. Accordingly, the scope of the present disclosure is not confined to any subset of embodiments and is confined only by the limitations set out in the appended claims.

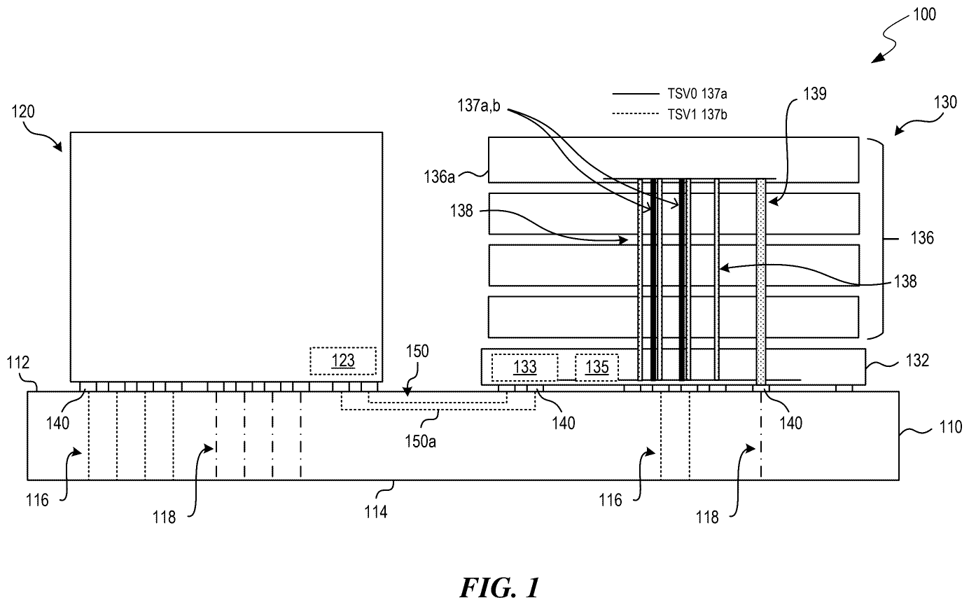

FIG. 1 is a partially schematic cross-sectional diagram of a SiP device 100 in accordance with an embodiment of the present disclosure. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110. The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

In the illustrated environment, the host device 120 can include a variety of components, such as a processing unit (e.g., CPU/GPU/TCU, etc.), one or more registers, one or more cache memories, and/or a variety of other components. For example, in the illustrated environment, the host device 120 includes a host IO circuit 123 that can direct signals to and/or from the HBM device 130 through the communication channels 150, which can include DQ (data) signals 150a. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory stacks 136 (four illustrated in FIG. 1) carried by the interface die 132. Each of the memory stacks 136 can include one or more DRAM dies (not shown in FIG. 1). Each memory stack 136 may encompass a physical and/or logical arrangement of one or more dies and can be associated with a stack ID (SID). The HBM device 130 also includes one or more signal TSVs 138 (two illustrated in FIG. 1), one or more DQ signal TSVs 137a,b (two sets illustrated in FIG. 1) and one or more power TSVs 139 (one illustrated in FIG. 1) each extending from the interface die 132 to an uppermost memory stack 136a. As discussed further below, DQ signal TSVs 137a and 137b represent different paths (TSV0 and TSV1, respectively) that a DQ signal can take from a DQ pin to the DRAM. The power TSV(s) 139 provide power (e.g., received from one or more of the external power TSVs 118) to the interface die 132 and each of the memory stacks 136. The signal TSVs 138, which include TSVs for carrying control and address signals, and the DQ signal TSVs 137a,b, which carry DQ signals, communicably couple a corresponding memory die in each of the memory stacks 136 to a HBM memory controller circuit 133 in the interface die 132 (in addition to various other circuits in the interface die 132). In turn, the HBM memory controller circuit 133 can direct DQ, control, and/or address signals to and/or from the host device 120 and/or an external component (e.g., an external storage device coupled to one or more of the external signal TSVs 116 and/or the like). In some embodiments of the present disclosure, the HBM device 130 can include a bus switching circuit 135 between the HBM memory controller circuit 133 and the signal TSVs 138. As discussed further below, the bus switching circuit 135 can receive the DQ, control, and/or address signals from the HBM memory controller circuit 133 and select the TSV path to be used by the DQ signals when communicating between the HBM device 130 and the host device 120 (and/or an external device).

Additional details on the HBM devices, SiP devices having HBM devices, and associated systems and methods, are set out below. For ease of reference, simplified assemblies of semiconductor packages (and their components) are described herein. It is to be understood, however, that the semiconductor assemblies (and their components) can be moved to, and used in, different spatial orientations without changing the structure and/or function of the disclosed embodiments of the present technology. Additionally, embodiments of the semiconductor packages (and their components) are sometimes described herein with reference to control, read, and/or write signals. It is to be understood, however, that the signals can be described using other terminology and/or the embodiments can use other types of signals that are not discussed without changing the structure and/or function of the disclosed embodiments of the present technology.

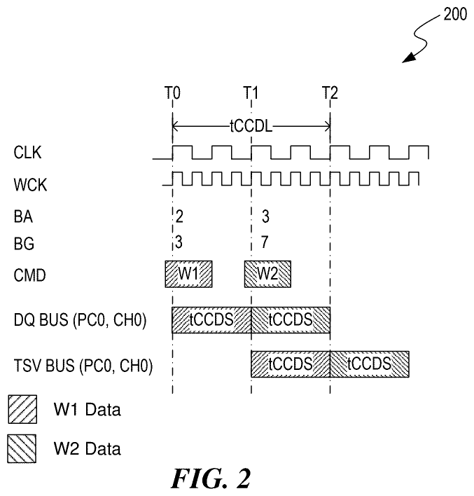

FIG. 2 illustrates a timing diagram 200 for a related art SiP that shows data transfer during a write operation using a set of TSVs (“TSV bus”). The timing diagram can correspond to a related art HBM device with a data rate of 8 Gbps. For brevity, a read timing diagram is not shown. As used herein a “TSV bus” can refer to one or more TSVs carrying DQ signals. For example, based on the context, a TSV bus can refer to all the TSVs or a subset of the TSVs in an HBM device (e.g., TSVs corresponding to a channel, a pseudo-channel, etc.). As seen in FIG. 2, the frequency of the system clock CLK determines the frequency of the write clock WCK, which can be, for example, twice the system CLK frequency. The WCK signal provides the timing for data transfer using, for example, double data rate (DDR). That is, data transfers occur on both the rising and falling edges of the WCK clock.

The CLK signal determines the duration of timing parameters, such as for example, column access timing parameters t_{CCDL}, t_{CCDS}, and t_{CCDR}, which can be set according to the standard for the HBM device. The timing parameter t_{CCDL} is the read/write (RD/WR) command delay between different banks (BAs) within the same bank group (BG), the timing parameter t_{CCDS} is the RD/WR command delay between different BGs, and the timing parameter t_{CCDR} is the RD command delay between different SIDs. As seen in timing diagram 200, the timing parameter t_{CCDL} is set to 4 CLK cycles and the timing parameter t_{CCDS} is set to 2 CLKs. The timing parameters are part of the interface protocol between a host device and HBM device, and the HBM device may provide to the host device the timing requirements for scheduling memory operations. That is, the HBM device may let the host device know the CLK cycle settings for timing parameters such as, for example, t_{CCDL} and t_{CCDS}. The host device observes any restrictions in the timing parameters when communicating with the HBM device. For example, based on the t_{CCDL} timing parameter, the host device will not schedule read or write commands to banks in the same bank group within the same t_{CCDL} CLK cycle period. That is, after sending a command (e.g., read, write, etc.) to a bank in a bank group, the host device will wait t_{CCDL} CLK cycles (e.g., 4 CLK cycles in related art SiPs) before scheduling another read or write command to a bank in the same bank group. With respect to the timing parameter t_{CCDS}, after a read or write command to a bank in a bank group, the host device will wait t_{CCDS} CLK cycles before scheduling another read or write command to a bank in a different bank group. The host device will not violate the timing protocols when scheduling memory commands to the HBM device. That is, the host device will wait at least the number of cycles specified by a timing parameter before issuing successive commands that implicate a timing parameter (e.g., certain timing parameters specify a minimum number of cycles in between commands of certain types). Those skilled in the art understand the interface protocol between the host device and the HBM device and thus, for brevity, will not be further discussed except as needed to explain embodiments of the present disclosure.

As seen in timing diagram 200, the t_{CCDL} CLK cycle period is set to 4 CLK cycles and the timing parameter t_{CCDS} is set to 2 CLKs and t_{CCDS} CLK cycle period is set to 2 CLKs. The timing parameters are set to ensure that the timings of the memory arrays in the dies, the timing through the TSV bus, and the timings of the DQ bus are synchronized to ensure proper operation of the HBM device. For example, in a related art HBM device having a CLK frequency of 2 GHz and a bitrate of 8 gigabits per second (Gbps) (using a burst length of 8), the t_{CCDL} CLK cycle period is set to 4 CLK cycles and the t_{CCDS} CLK cycle period is set to 2 CLKs synchronize data transfer between an HBM device and a host device so as to keep the DQ bus saturated (e.g., DQ bus for PC0, channel 0). That is, as seen in FIG. 2, to maintain the 8 Gbps rate, the DQ bus corresponding to a channel or pseudo-channel is available for write operations every 2 CLK cycles (e.g., a new set of 32-byte pseudo-channel data is available for transmission on the DQ bus every 2 CLK cycles). Similarly, for read operations (not shown), the DQ bus will be available to receive new 32-byte pseudo-channel data every 2 CLK cycles.

As seen in FIG. 2, two BGs can be accessed during a t_{CCDL} CLK cycle period (4 CLK cycles), such as, for example, bank 2 in BG3 and bank 3 in BG7. Once the W1 write command to bank 2 in BG3 is issued, the host device (e.g., host device 120) will wait t_{CCDS} CLK cycles (2 CLK cycles) before issuing the W2 write command to bank 3 in BG7. Depending on how the bank groups are arranged in the HBM device, BGs can be in the same stack or in different stacks (also referred to herein as “SIDs”). As seen in FIG. 2, the two write commands to BG3 and BG7 take t_{CCDL} CLK cycles (4 CLK cycles). So t_{CCDL} CLK cycles after scheduling the W1 write command to BG3, the host device can schedule another write command to a different bank in BG3, if needed. Prior to the completion of t_{CCDL} CLK cycles after the first command, the host device will not issue another command to the same bank group.

For purposes of explanation, it is assumed that BG3 and BG7 use the same TSV bus (same set of TSVs) for communicating with the DQ bus. Also, for clarity, the W1 data flow and the W2 data flow are identified with hashed lines going in different directions. At time T0, based on a write command W1 to bank 2 of BG 3 with a BL of 8, 32 bytes of data are transmitted using 2 CLK cycles (4 WCK cycles) to the DQ bus (e.g., DQ bus for PC0, CH0). At time T1, the W1 data is transferred to bank 2 over the TSV bus, which communicatively couples to BG3. As seen in FIG. 2, the transmission to bank 2 of BG3 takes a t_{CCDS} CLK cycles (2 CLK cycles). Still at time T1, based on a write command W2 to bank 3 of BG7, 32 bytes of data are transmitted to the DQ bus after W1 data transfer to the DQ bus has finished. At time T2, the W1 data is finished transferring over the TSV bus for BG 3. The W1 data transfer over the TSV bus takes t_{CCDS} CLK cycles (2 CLK cycles), at which point the TSV bus is free to be used for another transfer. At time T2, the W2 data is transferred over the TSV bus, which communicatively couples to BG7. In the related art system of FIG. 2, the bank groups are accessed sequentially, and the HBM device uses a t_{CCDL} CLK cycle period of 4 CLK cycles and a t_{CCDS} CLK cycle period of 2 CLK cycles to ensure that the memory array timing, the TSV bus timing, the DQ bus timing are synchronized, so that data is not lost and the DQ bus is saturated.

There is, however, a need to increase bandwidth of the communication between the host device and the HBM device on, e.g., communication channels 150 (e.g., from 8 Gbps to greater than 8 Gbps such as, for example, 16 Gbps, 24 Gbps, 32 Gbps or more). To achieve this, more BGs can be opened up (e.g., per channel or per pseudo-channel) for read/write operation during, for example, the duration t_{CCDL} and the data rate at the DQ pins can be increased accordingly. However, one potential issue is that, because the data paths in the HBM device operate at tight timing margins, an increase in the data rate at the DQ pins can result in a slip in the timing margins. That is, an increased data rate can mean that the memory array timing, the TSV bus timing, and/or the DQ bus timing are no longer synchronized. A solution can be to the t_{CCDS} and t_{CCDR} CLK cycle periods (e.g., setting them to 3 or 4 CLK cycles instead of 2 CLK cycles) to ensure data is not lost when transferring from/to the DQ bus, which operates at a timing of t_{CCDS} CLK cycles (2 CLK cycles) based on external requirements. However, by waiting extra CLK cycles, the data transfers in the HBM device can be less efficient because the DQ bus may no longer be saturated (e.g., gaps or bubbles may exist when there is no data to process).

Another potential issue is that the TSV bus must be able to handle the increased data rate. A solution can be to increase the TSV bus timing frequency to increase the data rate through the TSV bus, but this means that the clock voltage will need to be raised. If the clock voltage is raised, the use of low swing signaling may no longer be an option, as there may not be enough time for TSV bus voltage to swing between low and high. Accordingly, increasing the TSV bus timing frequency is not desirable because the power consumption in the HBM device will also increase.

Further, memory array timings are set such that read/write operations on a BG require access to the TSV bus for a predetermined period of time. For example, a related art HBM device can perform read/write operations at an 8 Gbps data rate on two BGs during a t_{CCDL} CLK cycle period (see FIG. 2). For each read/write operation, the memory array timings require access to the appropriate TSV bus for 2 CLK cycles (1 ns) before the TSV bus can be released for the next read/write operation. Thus, the t_{CCDL} CLK cycle period in the related art HBM device is set to 4 CLK cycles (2 ns) to accommodate the two BGs opened during the t_{CCDL} CLK cycle period. Accordingly, with a t_{CCDL} CLK cycle period of 4 CLK cycles (time duration of 2 ns) and t_{CCDS} CLK cycle period of 2 CLK cycles (time duration of 1 ns), the memory array timing is synchronized with the TSV bus timing and the DQ bus timing in the related art HBM device.

Embodiments of the present disclosure enable an increased bandwidth in comparison to related art HBM devices. To increase the bandwidth, the number of BGs accessed during a t_{CCDL} CLK cycle period can be increased (e.g., per channel or per pseudo-channel), and the t_{CCDL} CLK cycle period can be increased as appropriate to accommodate the increased number of BGs. For example, to double the bandwidth, the number of BGs per t_{CCDL} CLK cycle period can be increased (e.g., per channel or per pseudo-channel) to 4 BGs and the t_{CCDL} CLK cycle setting can be set to 8 CLK cycles. In addition, the frequency of the CLK clock can be doubled such that the data rate at the DQ pins is 16 Gbps. However, with the higher clock frequency, the memory array timings and the TSV bus timings will be out of synchronization. For example, if the data rate is doubled from 8 Gbps to 16 Gbps, with a t_{CCDL} CLK cycle period of 4 CLK cycles and a t_{CCDS} CLK cycle period of 2 CLK cycles, the t_{CCDL} time duration will go from 2 ns to 1 ns and the t_{CCDS} time duration will go from 1 ns to 0.5 ns. As discussed above, the memory array timings are synchronized when the t_{CCDL} time duration is 2 ns and the t_{CCDS} time duration is 1 ns. The memory arrays may not be able to cycle through the increased number of bank groups in less than 2 ns. A solution could be to increase the duration of the t_{CCDS} CLK cycle period to 4 CLK cycles and/or to appropriately modify the timing parameters in the memory array to accommodate the higher frequency of the TSV bus. However, changing the t_{DDCS} CLK cycle period to 4 CLK cycles also means that the t_{CCDR} CLK cycle period will need to change to 4 CLK cycles, which is undesirable because the DQ bus will not be saturated, as discussed above. In addition, redesigning the memory array architecture is also not desirable because of the complexity and thus may not be feasible or cost effective. Accordingly, it is desirable to increase the bandwidth on the HBM device while maintaining the same memory array timing and maintaining t_{CCDR} at 2 CLK cycles to keep the DQ bus saturated. In addition, it is desirable to keep power consumption on the HBM device as low as possible.

A potential option that may allow the t_{CCDL} CLK cycles to remain at 4 CLK cycles (a time duration of 1 ns) is to open two bank groups for access at the same time. This option keeps the memory array timing in synchronization and also accommodates the increased data rate. However, such a design means that the two bank groups are fixedly paired and must be accessed as a single unit. This configuration effectively reduces the number of independently addressable bank groups and thus reduces the flexibility of the HBM device memory scheduler in selecting memory banks during read/write operations. Accordingly, it is desirable to increase the bandwidth of HBM devices without changing the memory array structure of related art HBM devices (e.g., HBM devices following the JEDEC Standard, High Bandwidth Memory DRAM (HBM4) Specification) and/or changing the number of addressable bank groups. In addition, it is also desirable to maintain t_{CCDR} at 2 CLK cycles to keep the DQ bus saturated and to keep power consumption on the HBM device as low as possible.

In embodiments of the present disclosure, three or more BGs can be opened (e.g., per channel or per pseudo-channel) during a t_{CCDL} CLK cycle period to increase the bandwidth of the HBM device. In addition, the t_{CCDL} CLK cycle period can be extended (e.g., to 8 CLK cycles, 12 CLK cycles, 16 CLK cycles, etc.) accordingly to accommodate the greater number of BGs, and the t_{CCDS} and t_{CCDR} CLK cycle periods can be set at 2 CLK cycles to keep the DQ bus saturated. To help synchronize the TSV bus timing and the memory array timing, instead of keeping the TSV bus timing at t_{CCDS} CLK cycles, as in prior art devices, exemplary embodiments of the present disclosure set the TSV bus timing to a CLK cycle period corresponding to a ratio of t_{CCDL}/t_{CCDS} (herein after “timing ratio” or “timing ratio t_{CCDL}/t_{CCDS}”), which provides the memory arrays more access time to the TSV bus. In some embodiments, the addition of the timing ratio t_{CCDL}/t_{CCDS} can be a change in the firmware and/or the basic input/output system (BIOS) of the HBM device. The addition of the timing ratio t_{CCDL}/t_{CCDS} represents a change to the specification or interface between the HBM device and host device.

In addition to the timing ratio t_{CCDL}/t_{CCDS}, to keep the overall data rate through the TSVs the same as that of the DQ bus without incurring certain shortcomings (e.g., raising the voltage of the TSV bus). That is, embodiments of the present disclosure increase the number of available TSV data paths (e.g., per channel and/or pseudo-channel) so that a greater amount of data can be transmitted over the TSVs at any given time. By using multiple TSV data paths, the DQ signals on consecutive commands (read or write) can use separate TSV paths in a “pipeline” type arrangement. This provides more transmission time between the DRAM and the DQ bus for the DQ signals and thus, the data rate over a given TSV data path can be lower than that of the DQ bus while the data rate across all TSV paths matches that of the DQ bus. Thus, in embodiments of the present disclosure, the data rate (and corresponding voltage) through an individual TSV or TSV bus can be kept low enough to permit low swing signaling while still keeping the overall data rate on the TSVs equal to that of the DQ bus.

For example, in some embodiments, an HBM device can have a data rate of 16 Gbps with a system clock CLK frequency of 4 GHz. The number of BGs that are opened (e.g., per channel or per pseudo-channel) can be 4 to accommodate the increased bandwidth and the t_{CCDL} CLK cycles can be set to 8 CLK cycles (2 ns) to accommodate the 4 BGs. In addition, in some embodiments, to keep the overall data rate through the TSVs the same as the data rate through the DQ bus, additional TSV paths are added, for example, to each channel and/or pseudo-channel in the HBM device. Further, in some embodiments, the t_{CCDS} CLK cycle period is maintained at 2 CLK cycles (0.5 ns) to keep the DQ bus saturated and in synchronization with external communications, and the TSV bus timing, which can be set to a timing ratio t_{CCDL}/t_{CCDS} can correspond to 4 CLK cycles (Ins). A TSV bus timing of 1 ns will be the same as the related art HBM device operating at 8 Gbps. Accordingly, the memory array timing need not be changed to accommodate the higher bandwidth of embodiments of the present disclosure. Additional details of embodiments of the present disclosure are discussed below.

In the following discussion, reference will be made to DQ pins, channels, pseudo-channels, and corresponding TSVs. Those skilled in the art understand that, depending on the architecture of the HBM device, the number of TSVs per DQ pin can be a relationship that is something other than a one-to-one ratio. For example, based on a burst length (BL) of 8, there can be 8 TSVs per DQ pin. Depending on the design, other HBM devices can have other TSVs/DQ pin ratios such as, for example, 4 TSVs/DQ pin, 1 TSV/DQ pin, etc. Accordingly, while the following discussion focuses on TSV buses and DQ pins, those skilled in the art understand that more than one TSV can correspond to a DQ pin even if not explicitly stated.

In some embodiments, a TSV bus, comprising a set of one or more TSVs, can be associated with a DQ bus having a set of DQ pins in a HBM device. The DQ bus can correspond to, for example, a channel, a pseudo channel, or some other grouping of DQ pins. In some embodiments more than one TSV bus can be associated the DQ bus (e.g., channel, pseudo-channel, etc.). Having more than one TSV bus associated with each DQ bus (e.g., a channel, a pseudo-channel, etc.) provides more transmission paths for the data, which allows for a slower data rate through each TSV or TSV bus, while the data rate across all TSVs equals that of the DQ bus. In some embodiments, there can be N number of TSV buses for each DQ bus (e.g., channel, pseudo-channel, etc.), where N is a positive integer greater than 1. For example, as discussed further below, in some embodiments, each pseudo-channel PC0 or PC1 can be associated with two TSV buses TSV0 and TSV1 (e.g., TSV0 and TSV1 for PC0, and TSV0 and TSV1 for PC1).

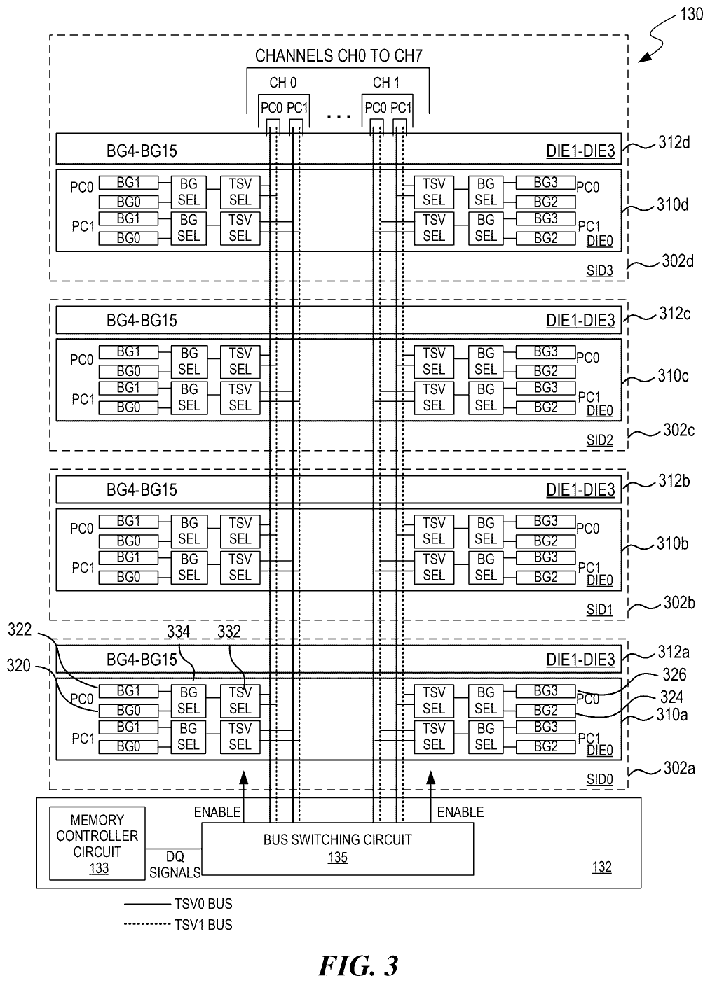

FIG. 3 illustrates a block diagram of the HBM device 130 of FIG. 1. The illustrated embodiment in FIG. 3 has a 4N architecture in that the HBM device 130 includes four stacks SID0-SID3, which can be the same as stacks 136 in FIG. 1, and each of the stacks SID0-SID3 (labeled 302a-d, respectively) can include four DRAM dies DIE0-DIE3 (die DIE0 in each stack is labeled 310a-d, respectively, and dies DIE1-DIE3, in each stack are collectively labeled 312a-d, respectively). However, other embodiments can have other arrangements in which the number of stacks and/or dies can be fewer or greater. For example, in some embodiments, the number of stacks and/or dies can be 1, 2, or 3.

Each die 310a-d and 312a-d can have one or more channels that provide independent data access to one or more banks of memory arrays (not shown). For example, in the embodiment of FIG. 3, channels 0 and 1 and the corresponding pseudo-channels PC0 and PC1 for each channel are shown extending through the stacks 302a-d. Die 310a-d in each stack has bank groups BG0 320 and BG 1 322 (for clarity, only BG0 and BG1 in stack 302a and die 310a are labeled), which can communicatively couple to channel 0, and bank groups BG2 324 and BG3 326 (for clarity, only BG0 and BG1 in stack 302a and die 310a are labeled), which can communicatively couple to channel 1. Each bank group 320, 322, 324, 326 can include one or more memory banks (e.g., 8 memory banks) that each include one or more memory arrays. The other channels 2-7 (not shown) have similar configurations but communicatively couple to different bank groups in different dies. For example, the other channels may couple to BG4 through BG15.

In some embodiments, each channel 0-7 can be split into two pseudo-channels that operate semi-independently such as, for example, pseudo-channel PC0 corresponding to DQ bits 0-31 and pseudo-channel PC1 corresponding to DQ bits 32-64. The channels and/or pseudo-channels can provide independent access to corresponding BGs, where each BG can include one or more banks. For example, if a die has 16 banks, each BG can have four banks and an independent channel can provide access to that BG. A die can include fewer banks than 16 such as, for example, 4 banks, 8 banks, etc. In some embodiments, a die can include more than 16 banks. Similarly, the number of BGs in a die can be fewer or greater than four. Segmenting a memory device into banks and bank groups is known in the art and thus, for brevity, will not be further discussed. In addition, those skilled in the art understand that an HBM device can have different arrangements with respect to the number of dies, banks, bank groups, channels, and/or pseudo-channels than in the disclosed embodiments and still be consistent with the present disclosure.

The following description focuses on pseudo-channel PC0 in SID0 302a and DIE0 310a. However, the description is applicable to pseudo-channel PC1, the other stacks 302b-d, and the other dies 310b-d and 312a-d, and thus for brevity and clarity is not repeated. As seen FIG. 3, the bank groups 320, 322, 324, and 326 are each split into two sets, with each set corresponding to a different pseudo-channel (PC0 or PC1). The banks groups 320 and 322 for the PC0 set can selectively and communicatively couple to either the TSV0 bus or the TSV1 bus for PC0 of channel 0. A TSV select circuit 332 (for clarity only the TSV select circuit for PC0 in stack 302a of die 310a is labeled) selects which bus (TSV0 or TSV1) the bank groups 320 and 322 communicatively couple with based on the enable signals from bus switching circuit 135, discussed below. During read or write operations to a bank in either bank group 320 or 322, TSV select circuit 332 ensures the bank group has access to the TSV bus (either the TSV 0 bus or the TSV1 bus) for a CLK cycle period that is based on the timing ratio t_{CCDL}/t_{CCDS}. During the t_{CCDL}/t_{CCDS} CLK cycle period, another bank group cannot communicatively couple to the TSV bus (TSV0 or TSV1) that is being used. However, the TSV bus that is not currently being used can be accessed by another bank group.

A BG select circuit 334 (for clarity only the BG select circuit for PC0 in stack 302a of die 310a is labeled) selects which bank group (e.g., 320, 322) should communicatively couple to the TSV select circuit 332. In some embodiments, the determination as to which BG should be communicatively coupled to which TSV bus (TSV0 or TSV1) can be performed in the bus switching circuit 135 (and/or another circuit in the HBM device) based on, for example, SID, BG, and/or BA information in the read/write commands from the HBM memory controller circuit 133. The BG select circuit 334 ensures only one of the bank groups 320 or 322 is communicatively coupled to the TSV select circuit 332 at any given time. The BG select circuit 334 also ensures that the same bank group is not accessed within the t_{CCDL} CLK cycle period. The operational description for bank groups 320 and 322 corresponding to PC1 and the other bank groups 324 and 326 will be similar to that of bank groups 320 and 322 for PC0, and thus, for brevity, will not be discussed. In addition, the bank groups in the other dies 310b-d and 312a-d and in the other stacks 302b-d have similar configurations, and thus for brevity will not be discussed. Although the embodiment in FIG. 3 shows two BGs are first communicatively coupled to BG select circuit that is then communicatively coupled a TSV select circuit, in other embodiments, based on the arrangement, each BG can communicatively couple directly to the TSV select circuit without the intervening BG select circuit. Those skilled in the art understand that the numbering and specific configuration of bank groups and banks can be different from that shown in FIG. 3, but the concepts discussed herein are applicable to other bank group configurations.

In related art systems each channel (when pseudo-channels are not used) or each pseudo-channel includes one TSV bus per channel or pseudo-channel, as appropriate. However, in exemplary embodiments of the present disclosure each channel (when pseudo-channels are not used) or pseudo-channel has N number of TSV buses that can be selectively accessed, where N is an integer that is greater than 1 (e.g., 2, 3, 4, etc.). In some embodiments, to simplify the design of timing circuits, N can be limited to even integers. That is, each channel or pseudo-channel may have an even number of TSV buses to select from. As discussed further below, as more BGs are opened during a t_{CCDL} CLK cycle period to increase bandwidth, the extra TSV buses, along with a TSV bus timing corresponding to a timing ratio t_{CCDL}/t_{CCDS}, can provide different data paths to help relax the timing constraints on the TSV bus.

For brevity, embodiments having pseudo-channels with each pseudo-channel having two corresponding TSV buses are described below. However, those skilled in the art understand that the concepts discussed below are also applicable to embodiments where the channels are not split into pseudo-channels and/or where more than two TSV buses are associated with a pseudo-channel or channel.

As seen FIG. 3, each channel includes two pseudo-channels, a PC0 channel and a PC1 channel, and each pseudo-channel PC0, PC1 includes a TSV0 bus (represented by solid line) and a TSV1 bus (represented by a dotted line). For clarity, only the TSV0 and TSV1 buses for each pseudo-channel of channels 0 and 1 are shown, but those skilled in the art understand that the other pseudo-channels can also include a TSV0 bus and a TSV1 bus. As seen in FIG. 3, a bus switching circuit 135 is located in interface die 132 along with the HBM memory controller circuit 133. However, some or all of the functions of bus switching circuit 135 can be incorporated into the stack dies, the HBM memory controller circuit 133, and/or another circuit. The HBM memory controller circuit 133 controls external access to the DQ bus and manages the DQ signals to and from the bus switching circuit 135 based on the memory operation (e.g., read, write, etc.). Configuration and operation of HBM memory controller circuits are known to those skilled in the art and thus, for brevity, will not be discussed further. The bus switching circuit 135 communicatively couples to the HBM memory controller circuit 133 to receive/transmit the DQ signals for each pseudo-channel from/to the HBM memory controller circuit 133 and, based on the address, control, and/or data signals from HBM memory controller circuit 133, selects and communicatively couples to the appropriate TSV bus (TSV0 bus or TSV1 bus) based on the pseudo-channel corresponding to the read/write operation. In addition, based on based on the address, control, and data signals from HBM memory controller circuit 133, the bus switching circuit 135 sends enable signals to the appropriate TSV select circuit 332 in the dies.

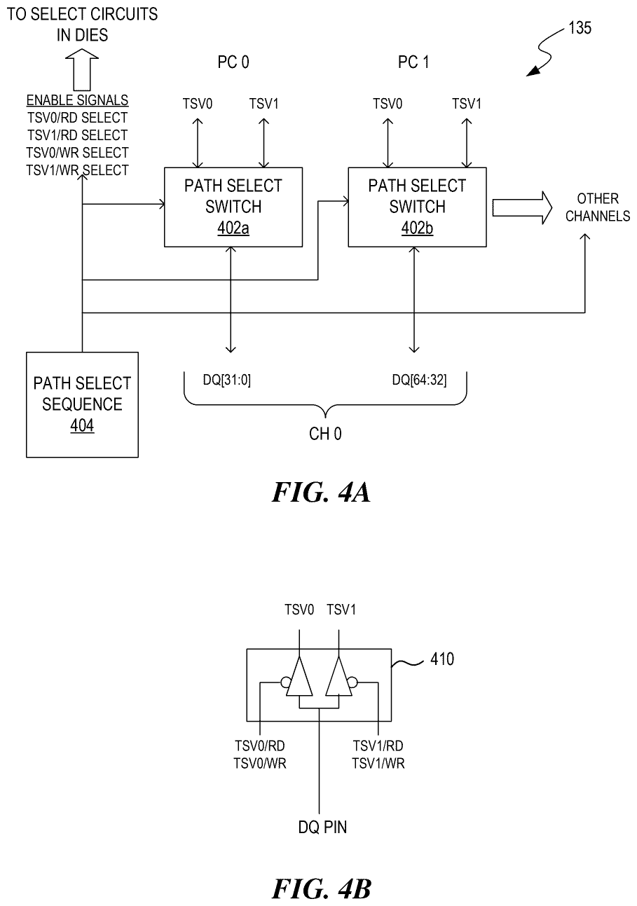

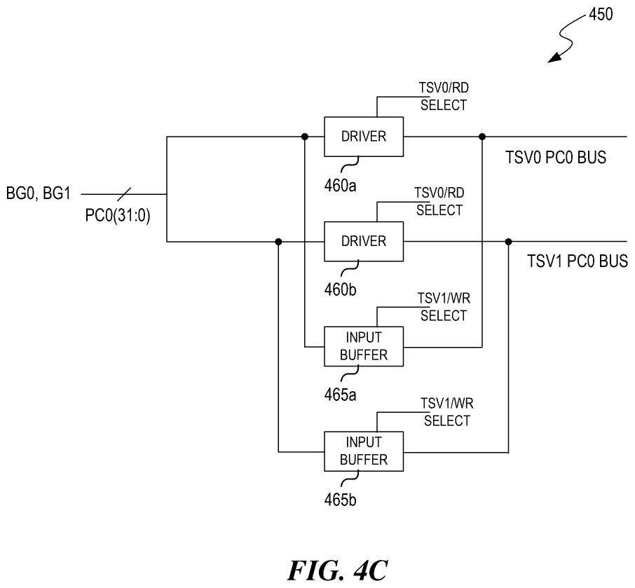

For example, FIG. 4A is a block diagram showing a portion of the bus switching circuit 135 that selects and communicatively couples to the TSV bus for channel 0 and sends enable signals. For brevity and clarity, FIG. 4A only shows pseudo-channels PC0 and PC1 of channel 0. However, those skilled in the understand that selection of the appropriate TSV busses for other channels will be similar. In some embodiments, each path select switch 402 can correspond to a pseudo-channel bus and can include multiple bit-switches corresponding to individual DQ pins (see FIG. 4B). As seen in FIG. 4A, path select switch 402a communicatively couples DQ pins 0-31 of PC0 of channel 0 to the TSV0 bus or the TSV1 bus for PC0. Similarly, path select switch 402b communicatively couples DQ pins 32-64 of PC1 of channel 0 to the TSV0 bus or the TSV1 bus for PC1.

In some embodiments, based on the address, control, and/or data signals from HBM memory controller circuit 133, the path select sequence circuit 404 selects the appropriate TSB bus and transmits enable signals to the appropriate patch select switch 402 and to the appropriate TSV select circuit 320 or 322 in the appropriate die. The path select sequence circuit 404 and/or another circuit can include one or more processors, memory, look-up-table, and/or other circuits to determine the appropriate TSV bus, channel, pseudo-channel, stack, die, and/or TSV select circuit to select based on address, control, and/or data information from the HBM memory controller circuit 133. As discussed further below, the enable signals can include a TSV0/RD select signal, a TSV1/FD select signal, a TSV0/WR select signal, and a TSV1/WR select signal. However, other embodiments can include more or fewer signals based on the configuration of the HBM device. Based on the enable signals to the path select switches 402, a data path between the DQ bus and the TSV0 bus is selected and the DQ bus and TSV0 bus is communicatively coupled; or a data path between the DQ bus and the TSV1 bus is selected and the DQ bus and TSV1 bus is communicatively coupled; or no data path is selected.

FIG. 4B shows an embodiment of an individual bit-switch 410 that can be included in the path select switch 402. Each path select switch 402 can include a plurality of bit-switches 410 with each bit-switch 410 corresponding to a bit in the appropriate pseudo-channel. As seen in FIG. 4B, the bit-switch 410 can include one or more tri-state inverter circuits (or another appropriate switch circuit) to communicatively couple the DQ pin to the appropriate TSV or TSVs to provide a bi-directional data path. The bit-switch 410 can receive enable signals from the path select sequence circuit 404 and select the appropriate path between the appropriate TSV (TSV0 or TSV1) and the DQ pin. For example, if the TSV0/RD select signal or the TSV0/WR select signal is enabled, a data path between the DQ pin and a TSV on the TSV0 bus is selected. If the TSV1/RD select signal or the TSV1/WR select signal is enabled, a data path between the DQ pin and a TSV on the TSV1 bus is selected. If none of the signals are enabled, then no data path is selected (e.g., data is not being transmitted/received to/from that pseudo-channel). In some embodiments, instead if two signals (e.g., a TSV0/RD select signal and the TSV0/WR signal), only one signal for the TSV0 bus can be used. Similarly, only one signal for the TSV1 bus can be used.

In operation, when the HBM memory controller circuit 133, for example, based on commands from the host device, sends data to be written to a memory bank over a pseudo-channel, the patch select switch 402 for that pseudo-channel selects either the TSV0 bus or the TSV1 bus based on the enable signals and communicatively couples the DQ bus to the appropriate TSV bus. Similarly, when receiving data read from a memory bank based on, for example, commands from the host device, the path select switch 402 selects and communicatively couples the appropriate TSV bus (e.g., TSV0 or TSV1) to the DQ bus based on the enable signals. In some embodiments, the enable signals can be, for example, hardwired, to each path select switch 402. In other embodiments, the enable signals include switch identification information and are communicated over a bus to some or all the path select switches 402.

In some embodiments, path select sequence circuit 404 transmits the enable signals in a pattern such that the enable signals alternate (“ping-pong”) between selecting the TSV0 bus and selecting the TSV0 bus. The alternating sequence can be based on the t_{CCDS} CLK cycle period, which can be, for example, 2 CLK cycles. For example, the bus switching circuit 135 can alternatively select between a first TSV bus and a second TSV bus every t_{CCDS} CLK cycle period, for example, during a t_{CCDL} CLK cycle period. In other embodiments, the alternating sequence can be based on successive commands (e.g., read or write commands). For example, the bus switching circuit can alternatively select between a first TSV bus and a second TSV bus during successive read commands or successive write commands. In other embodiments, the TSV bus selection can be determined on other criteria such as whether a TSV bus (e.g., a default TSV bus) is busy before selecting the other bus.

As discussed above, the bus switching circuit 135 (and/or another circuit) transmits the enable signals (e.g., TSV0/RD select, TSV0/WR select, TSV1/RD select, and TSV1/WR select) to the appropriate TSV select circuit 332 in the appropriate die. Based on the enable signals, each TSV select circuit 332 can direct the data to the proper pseudo-channel. For example, FIG. 4C illustrates a TSV select circuit 450, which corresponds to TSV select circuit 332 in FIG. 3, for pseudo-channel PC0 of channel 0. The TSV select circuits for the other pseudo-channels are similar. As seen in FIG. 4C, the TSV select circuit 450 can include a set of driver circuits 460a, 460b to transmit data from 320 or 322 (see FIG. 3) on the PC0 bus in die 310a to either the TSV0 PC0 bus or the TSV1 PC0 bus, as applicable. The TSV select circuit 450 can also include a set of input buffer circuits 465a, 465b to receive data from either the TSV0 PC0 bus or the TSV1 PC0 bus, as applicable, and transmit the data to the PC0 bus corresponding to bank groups 320 and 322 in die 310a.

To enable the drivers 460a, 460b and input buffers 465a, 465b, as discussed above, the TSV select circuit 450 can receive four enable signals, the TSV0/RD select signal, the TSV0/WR select signal, the TSV1/RD select signal, and the TSV1/WR select signal from, for example the bus switching circuit 135. The TSV0/RD select signal, when enabled, activates driver 460a to communicatively couple the PC0 bus to the TSV0 PC0 bus during read operations. Similarly, the TSV1/RD select signal, when enabled, activates driver 460b to communicatively couple the PC0 bus to the TSV1 PC0 bus during read operations. The TSV0/WR select signal, when enabled, activates input buffer 465a to communicatively couple the PC0 bus to the TSV0 PC0 bus during write operations. Similarly, the TSV1/WR select signal, when enabled, activates input buffer 465b to communicatively couple the PC0 bus to the TSV1 PC0 bus during write operations.

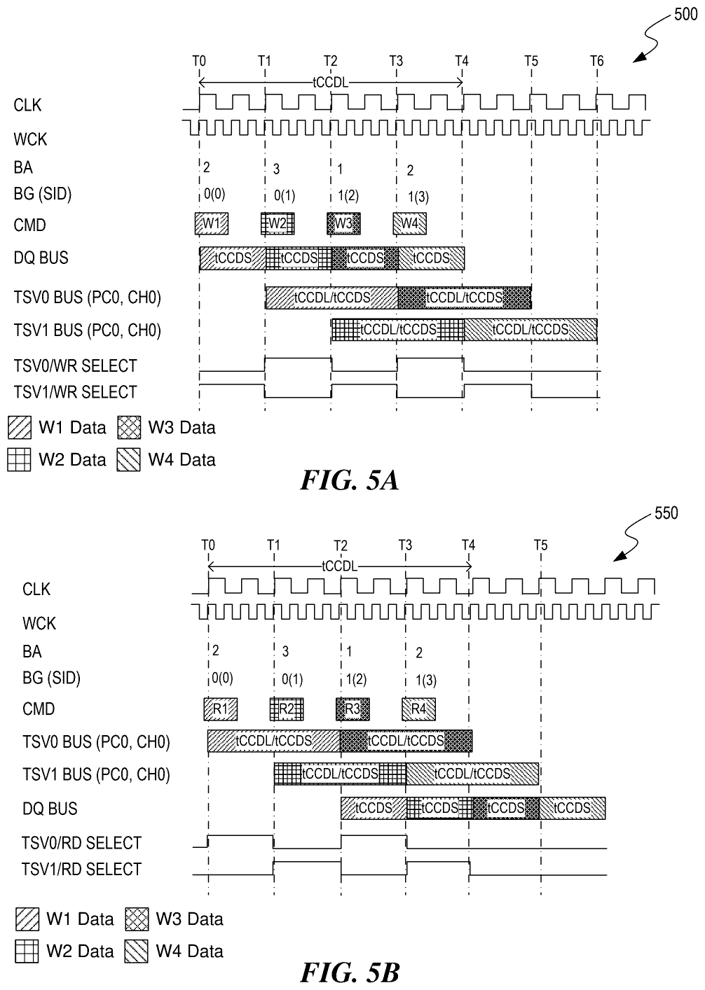

FIG. 5A illustrates a simplified timing diagram 500 for write operations that are consistent with the present disclosure. The timing diagram can correspond to an HBM device that has a data rate of 16 Gbps. As seen in the diagram, the write commands, which are separated by t_{CCDS} CLK cycles (2 CKL cycles), alternate between TSV buses (TSV0 and TSV1). For example, the write commands W1 and W3 correspond to TSV0, and the write commands W2 and W4 corresponds to TSV1. As seen in FIG. 5A, the data for each command can access the corresponding TSV bus for a CLK cycle period corresponding to the timing ratio t_{CCDL}/t_{CCDS}, which can be, for example, 4 CLK cycles. As discussed above, with a TSV bus timing of 4 CLK cycles (1 ns), the memory array timing need not be changed. In addition, there are four consecutive write commands that open 4 bank groups within the t_{CCDL} CLK cycle period (e.g., 8 CLK cycles). As discussed above, with a t_{CCDL} CLK cycle period of 8 CLK cycles (2 ns), the memory arrays can cycle through the bank groups and double the amount of data is transmitted in the same time period, as compared to related art HBM devices. For clarity, in FIG. 5A, the different W# data flows are identified using different hashlines and crosshatches.

The time from T0 to T4 corresponds to the t_{CCDL} CLK cycle period, which is 8 CLK cycles in this embodiment. As seen in FIG. 5A, 4 BGs can be opened (e.g., per channel or per pseudo-channel) for write operations during the duration t_{CCDL} CLK cycle period, which allows for more bandwidth than related art devices that only open 2 BGs. In the following embodiment, the banks being written to correspond to PC0 of channel 0 and thus, the TSV bus corresponds to PC0 of channel 0.

At time T0, based on a write command W1 to bank 2 of BG0 in SID0 with a BL of 8, 32 bytes of data are transmitted using 2 CLK cycles (4 WCK cycles) to the DQ bus from, for example, the host device 120 via HBM memory controller circuit 133. The 32-bytes for W1 can correspond to a pseudo-channel PC0 (e.g., based on the PC bit information in the address signal). At time T1, based on information from, for example, the host device, the HBM memory controller 133, and/or the bus switching circuit 135, the TSV0/WR select signal from path select sequence circuit 404 goes high (and the TSV1/WR select signal goes low) to select the TSV0 bus corresponding to BG0 in SID0 and the W1 data is transferred to bank 2 over the TSV0 bus. As seen in FIG. 5A, once the transmission starts, the bank 2 has access to the corresponding TSV0 bus for t_{CCDL}/t_{CCDS} CLK cycles, which in this case is 8/2=4 CLK cycles. In this embodiment, the 4 CLK cycles correspond to 1 ns. Accordingly, the memory array timings of bank 2 can remain the same as that of a related art HBM device at a data rate of 8 Gbs.

Still at time T1, based on a write command W2 to bank 3 of BG 0 in SID1, 32 bytes of data are transmitted to the DQ bus immediately after data transfer to the DQ bus for the write command W1 has finished. The 32-bytes for W2 can correspond to a pseudo-channel PC0. At time T2, while the W1 data is still being transferred over the TSV0 bus for BG 0 in SID0, the TSV1/WR select signal goes high (and the TSV0/WR signal goes low) to select the TSV1 bus corresponding to BG0 in SID1 and the W2 data is transferred to bank 3 over the TSV1 bus. Similar to the W1 write operation, once the transmission starts, bank 3 has access to the corresponding TSV1 bus for t_{CCDL}/t_{CCDS} CLK cycles (4 CLK cycles).

Still at time T2, based on a write command W3 to bank 1 of BG 1 in SID2, 32 bytes of data are transmitted to the DQ bus immediately after data transfer to the DQ bus for the write command W2 has finished. The 32-bytes for W3 can correspond to a pseudo-channel PC0. At time T3, bank 2 of BG0 in SID0 has completed the transfer and has released the TSV0 bus. Still at time T3, while the W2 data is still being transferred over the TSV1 bus for BG 0 in SID1, the TSV0/WR select signal goes high (and the TSV1/WR signal goes low) to select the TSV0 bus for BG 1 in SID2 and the W3 data is transferred to bank 1 over the TSV0 bus. Similar to the other write operations, once the transmission starts, bank 1 has access to the corresponding TSV1 bus for t_{CCDL}/t_{CCDS} CLK cycles (4 CLK cycles).

Still at time T3, based on a write command W4 to bank 2 of BG 1 in SID3, 32 bytes of data are transmitted to the DQ bus immediately after data transfer to the DQ bus for the write command W3 has finished. The 32-bytes for W4 can correspond to a pseudo-channel PC0. At time T4, bank 3 of BG0 in SID1 has completed the transfer and has released the TSV1 bus. Still at time T4, while the W3 data is still being transferred over the TSV0 bus for BG 1 in SID2, the TSV1/WR select signal goes high (and the TSV0/WR signal goes low) to select the TSV1 bus for BG 1 in SID3 and the W4 data is transferred to bank 2 over the TSV1 bus. Similar to the other write operations, once the transmission starts, bank 2 has access to the corresponding TSV1 bus for t_{CCDL}/t_{CCDS} CLK cycles (4 CLK cycles). At time T5, the transfer of W3 data to bank 1 of BG1 in SID2 is complete and the TSV0 bus is released. At time T6, the transfer of W3 data to bank 2 of BG1 in SID3 is complete and the TSV1 bus is released.

FIG. 5B illustrates a simplified timing diagram 550 for read operations that are consistent with embodiments of the present disclosure. The timing diagram can correspond to an HBM device that has a data rate of 16 Gbps. As seen in the diagram, the write commands, which are separated by t_{CCDS} CLK cycles (2 CKL cycles), alternate between TSV buses (TSV0 and TSV1). For example, the read commands R1 and R3 correspond to TSV0, and the write commands R2 and R4 corresponds to TSV1. As seen in FIG. 5B, the data for each command can access the corresponding TSV bus for a CLK cycle period corresponding to a timing ratio t_{CCDL}/t_{CCDS}, which can be, for example, 4 CLK cycles. As discussed above, with a TSV bus timing of 4 CLK cycles (1 ns), the memory array timing need not be changed. In addition, there are four consecutive read commands that open 4 bank groups within the t_{CCDL} CLK cycle period (e.g., 8 CLK cycles). As discussed above, with a t_{CCDL} CLK cycle period of 8 CLK cycles (2 ns), the memory arrays can cycle through the bank groups and double the amount of data is transmitted in the same time period, as compared to related art HBM devices. For clarity, in FIG. 5B, the different R# data flows are identified using different hashlines and crosshatches.

The time from T0 to T4 corresponds to the t_{CCDL} CLK cycle period, which is 8 CLK cycles in this embodiment. As seen in FIG. 5B, 4 BGs can be opened (e.g., per channel or per pseudo-channel) for read operations during the t_{CCDL} CLK cycle period, which allows for more bandwidth than related art devices that only open 2 BGs.

At time T0, based on information from, for example, the host device, the HBM memory controller 133, and/or the bus switching circuit 135, the TSV0/RD select signal from path select sequence circuit 404 goes high (and the TSV1/RD select signal is low) to select the TSV0 bus corresponding to PC0. Still at TO, based on a read command R1, 32 bytes of data (BL of 8) are read from bank 2 of BG 0 in SID0 corresponding to PC0 (e.g., based on the PC bit information in the address signal) for transfer over the TSV0 bus. As seen in FIG. 5B, once the transmission starts, the bank 2 has access to the corresponding TSV0 bus for t_{CCDL}/t_{CCDS} CLK cycles, which in this case is 8/2=4 CLK cycles. Accordingly, the memory array timings of bank 2 can remain the same as that of a related art HBM device at a data rate of 8 Gbs.

At time T1, while the data from bank 2 is still being transferred to the TSV0 bus, the TSV1/RD select signal goes high (and the TSV0/RD select signal goes low) to select the TSV1 bus corresponding to PC0. Still at T1, based on a read command R2, 32 bytes of data are read from bank 3 of BG 3 in SID1 corresponding to PC0 for transfer over the TSV1 bus. As seen in FIG. 5B, once the transmission starts, the bank 3 has access to the corresponding TSV1 bus for t_{CCDL}/t_{CCDS} CLK cycles (4 CLK cycles).

At time T2, the R1 read transfer over the TSV0 bus from bank 2 of BG0 in SID0 is finished and the TSV0 bus is released. In addition, the R1 read data is made available on the DQ bus for t_{CCDS} CLK cycles (2 CLK cycles) for transfer to, for example, the host device 120 via HBM memory controller circuit 133. Still at T2, while the data from bank 3 is still being transferred over the TSV1 bus, the TSV0/RD select signal goes high (and the TSV1/RD select signal goes low) to select the TSV0 bus corresponding to PC0. Based on a read command R3, 32 bytes of data are read from bank 1 of BG 1 in SID2 corresponding to PC0 for transfer over the TSV0 bus. Once the transmission starts, bank 1 has access to the corresponding TSV0 bus for t_{CCDL}/t_{CCDS} CLK cycles (4 CLK cycles).

At time T3, the R2 read transfer over the TSV1 bus from bank 3 of BG0 in SID1 is finished and the TSV1 bus is released. In addition, the R2 read data is made available on the DQ bus for t_{CCDS} CLK cycles (2 CLK cycles) for transfer to, for example, the host device 120 via HBM memory controller circuit 133. Still at T3, while the data from bank 1 is still being transferred over the TSV0 bus, the TSV1/RD select signal goes high (and the TSV0/RD select signal goes low) to select the TSV1 bus corresponding to PC0. Based on a read command R4, 32 bytes of data are read from bank 2 of BG 1 in SID3 corresponding to PC0 for transfer over the TSV1 bus. Once the transmission starts, bank 2 has access to the corresponding TSV1 bus for t_{CCDL}/t_{CCDS} CLK cycles (4 CLK cycles).

At time T4, the R3 read transfer over the TSV0 bus from bank 1 of BG1 in SID2 is finished and the TSV0 bus is released. In addition, the R3 read data is made available on the DQ bus for t_{CCDS} CLK cycles (2 CLK cycles) for transfer to, for example, the host device 120 via HBM memory controller circuit 133. At time T5, the R4 read transfer over the tSV1 bus from bank 2 of BG1 in SID3 is finished and the TSV1 bus is released. The R4 read data is made available on the DQ bus for t_{CCDS} CLK cycles (2 CLK cycles) for transfer to, for example, the host device 120 via HBM memory controller circuit 133.

As seen in FIGS. 5A and 5B, because there is more than one TSV bus, the bank groups opened during the t_{CCDL} CLK cycle period can be accessed in a staggered overlapping pattern. Accordingly, in exemplary embodiments of the present disclosure, the bandwidth can be increased while keeping the DQ bus saturated during read/write operations and while operating at a t_{CCDS} CLK cycle period equal to 2 CLK cycles. In addition, as seen in FIG. 5B, the command delay of read operations between different stacks SIDs is kept at a t_{CCDR} CLK cycle period of 2 CLK cycles, further ensuring the DQ bus remains saturated.

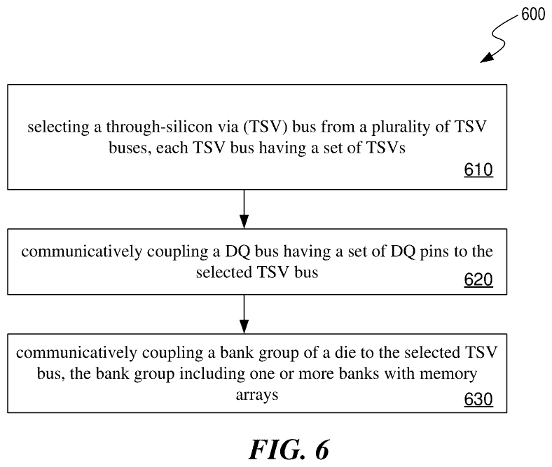

FIG. 6 illustrates a flow chart 600 showing the method steps performed by one or more processors and/or hardwired circuitry in the HBM device such as, for example, the HBM memory controller circuit 133, the bus switching circuit 135, and/or the TSV select circuits TSV SEL. In step 610, the HBM device selects a TSV bus from a plurality of TSV buses, each TSV bus having a set of TSVs. For example, as discussed above, based on information from the HBM memory controller circuit 133, the bus switching circuit 135 selects either the TSV0 bus or the TSV1 bus of a pseudo-channel (e.g., PC0 or PC1) of the appropriate channel to perform read/write operations.

In step 620, the HBM device communicatively couples a DQ bus having a set of DQ pins to the selected TSV bus. For example, as discussed above, in addition to selecting the appropriate TSV bus, the HBM memory controller circuit 133 communicatively couples the DQ bus of the appropriate channel to the selected TSV bus.

In step 630, the HBM device communicatively coupling a bank group of a die to the selected TSV bus, where the bank group includes one or more banks with memory arrays. For example, as discussed above, based on the enable signals from path select sequence circuit 404, the corresponding TSV select circuit 320 or 322 for the appropriate DRAM die and pseudo-channel communicatively couples the BG, which includes a bank with memory array, to the selected TSV bus (either TSV0 or TSV1).

From the foregoing, it will be appreciated that embodiment of the present disclosure provide increased bandwidth over related art HBM devices while ensuring that the DRAM memory array timings, the TSV bus timings, and the DQ bus timings are all synchronized. For example, it will be appreciated that, in some embodiment, the data rate at the DQ pins are increased while still keeping the same memory array as related art HBM devices. In addition, by relaxing the frequency cycle timings in the TSV bus, embodiments of the present disclosure can perform low voltage switching in the TSV to keep the power consumption low. Further, embodiments of the present disclosure increase the number of bank groups that can be opened during a t_{CCDL} CLK cycle period in comparison to a related art HBM device, while still maintaining a 4N architecture and the same number of banks.

In addition, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a processing unit carried by the base substrate; and
a high bandwidth memory (HBM) device carried by the base substrate and electrically coupled to the processing unit,
wherein the HBM device comprises:
an interface die, the interface die including a bus switching circuit configured to select a through-silicon via (TSV) bus from a plurality of TSV buses, each TSV bus having a set of TSVs, and communicatively couple a DQ bus having a set of DQ pins to the selected TSV bus; and
one or more stacks carried by the interface die, each stack having one or more dies, wherein each die includes a TSV bus select circuit that is configured to communicatively couple a bank group of the die to the TSV bus selected by the bus switching circuit of the interface die, the bank group including one or more banks with memory arrays.

2. The SiP device of claim 1, wherein the DQ bus corresponds to a pseudo-channel or channel of the HBM device.

3. The SiP device of claim 1, wherein the bus switching circuit selects between a first TSV bus and a second TSV bus during successive read commands or successive write commands.

4. The SiP device of claim 1, wherein the bus switching circuit selects between a first TSV bus and a second TSV bus every t_{CCDS} clock (CLK) cycle period during a t_{CCDL} CLK cycle period,
wherein t_{CCDL} corresponds to a delay between commands associated with different banks in a same bank group, and
wherein t_{CCDS} corresponds to a delay between commands associated with different banks in different bank groups.

5. The SiP device of claim 1, wherein a data rate at the DQ bus is greater than 8 gigabits per second (Gbps).

6. The SiP device of claim 1,
wherein, during a read or write operation to a bank in the bank group, each TSV select circuit has access to the TSV bus selected by the bus switching circuit of the interface die for a CLK cycle period of X CLK cycles, where X is a ratio of t_{CCDL}/t_{CCDS},
wherein t_{CCDL} corresponds to a delay between commands associated with different banks in a same bank group, and
wherein t_{CCDS} corresponds to a delay between different commands associated with banks in different bank groups.

7. The SiP device of claim 6, wherein more than two bank groups are accessed in a staggered overlapping pattern during a t_{CCDL} CLK cycle period.

8. A high bandwidth memory (HBM) device, comprising:
an interface die to operatively couple to a host device, the interface die including a bus switching circuit configured to select a through-silicon via (TSV) bus from a plurality of TSV buses, each TSV bus having a set of TSVs, and communicatively couple a DQ bus having a set of DQ pins to the selected TSV bus; and
one or more stacks carried by the interface die, each stack having one or more dies, wherein each die includes a TSV bus select circuit that is configured to communicatively couple a bank group of the die to the TSV bus selected by the bus switching circuit of the interface die, the bank group including one or more banks with memory arrays.

9. The HBM device of claim 8, wherein the DQ bus corresponds to a pseudo-channel or channel of the HBM device.

10. The HBM device of claim 8, wherein the bus switching circuit selects between a first TSV bus and a second TSV bus during successive read commands or successive write commands.

11. The HBM device of claim 8, wherein the bus switching circuit selects between a first TSV bus and a second TSV bus every t_{CCDS} clock (CLK) cycle period during a t_{CCDL} CLK cycle period,
wherein t_{CCDL} corresponds to a delay between commands associated with different banks in a same bank group, and
wherein t_{CCDS} corresponds to a delay between commands associated with different banks in different bank groups.

12. The HBM device of claim 8, wherein a data rate at the DQ bus is greater than 8 gigabits per second (Gbps).

13. The HBM device of claim 8,
wherein, during a read or write operation to a bank in the bank group, the respective TSV select circuit has access to the TSV bus selected by the bus switching circuit of the interface die during a read or write operation for a CLK cycle period of X CLK cycles, where X is a ratio of t_{CCDL}/t_{CCDS},
wherein t_{CCDL} corresponds to a delay between commands associated with different banks in a same bank group, and
wherein t_{CCDS} corresponds to a delay between commands associated with different banks in different bank groups.

14. The HBM device of claim 13, wherein more than two bank groups are accessed in a staggered overlapping pattern during a t_{CCDL} CLK cycle period.

15. A method, comprising:
selecting a through-silicon via (TSV) bus from a plurality of TSV buses, each TSV bus having a set of TSVs, and
communicatively coupling a DQ bus having a set of DQ pins to the selected TSV bus; and
communicatively coupling a bank group of a die to the selected TSV bus, the bank group including one or more banks with memory arrays,
wherein the DQ bus corresponds to a pseudo-channel or channel of a high bandwidth memory (HBM) device.

16. The method of claim 15, wherein the selecting further comprises selecting between a first TSV bus and a second TSV bus during successive read commands or successive write commands.

17. The method of claim 15, further comprising:
selecting between a first TSV bus and a second TSV bus every t_{CCDS} clock (CLK) cycle period during a t_{CCDL} CLK cycle period,
wherein t_{CCDL} corresponds to a delay between commands associated with different banks in a same bank group, and
wherein t_{CCDS} corresponds to a delay between commands associated with different banks in different bank groups.

18. The method of claim 15, further comprising:
operating the HBM device such that a data rate at the DQ bus is greater than 8 gigabits per second (Gbps).

19. The method of claim 15,
controlling access to the selected TSV bus during a read or write operation for a CLK cycle period of X CLK cycles, where X is a ratio of t_{CCDL}/t_{CCDS},
wherein t_{CCDL} corresponds to a delay between commands associated with different banks in a same bank group, and
wherein t_{CCDS} corresponds to a delay between commands associated with different banks in different bank groups.

20. The method of claim 19, further comprising:
accessing more than two bank groups in a staggered overlapping pattern during a time duration of t_{CCDL}.
